(19) United States
(12) Patent Application Publication
(10) Pub. No.: US 2026/0313851 A1
(43) Pub. Date: Oct. 8, 2026

(54) SYSTEM AND METHOD FOR PROVIDING SUPPLEMENTAL POWER AND COOLING TO ONE OR MORE COMPONENTS OF AN ELECTRICAL LOAD

(71) Applicant: Toyota Motor Engineering & Manufacturing North America, Inc., Plano, TX (US)

(72) Inventors: Chianing Wang, Mountain View, CA (US); Alexander T. Pham, San Jose, CA (US)

(73) Assignees: Toyota Motor Engineering & Manufacturing North America, Inc., Plano, TX (US); Toyota Jidosha Kabushiki Kaisha, Toyota-shi Aichi-ken (JP)

(21) Appl. No.: 18/926,416

(22) Filed: Oct. 25, 2024

(51) Int. Cl. H05K 7/20; H01M 8/04029

(52) U.S. Cl. CPC H05K 7/20772; H01M 8/04029; H05K 7/20172; H05K 7/20254; H05K 7/20281; H05K 7/20736; H01M 2250/10

(57) ABSTRACT

Described herein are systems and methods for providing supplemental power and cooling to an electrical load, such as one or more server racks. In one example, a system includes a closed loop having a first cooling device configured to cool a component of an electrical load, a first open loop configured to cool a coolant of the closed loop, and a second open loop having a second cooling device configured to selectively cool the component of the electrical load. The second cooling device may be configured to cool the component of the electrical load when a power source that emits water as a byproduct of operation is utilized to at least partially provide power to the electrical load.

### TECHNICAL FIELD

The subject matter described herein relates, in general, to systems and methods for providing supplemental power and cooling to one or more components of an electrical load.

### BACKGROUND

The background description provided is to present the context of the disclosure generally. Work of the inventor, to the extent it may be described in this background section, and aspects of the description that may not otherwise qualify as prior art at the time of filing, are neither expressly nor impliedly admitted as prior art against the present technology.

Some data centers offer computational resources provided by server racks that contain numerous graphics processing units (“GPUs”) and/or central processing units (“CPUs”). Among other things, these GPUs can be used to perform machine learning (“ML”) based training to train a model and also machine learning inferencing, which is the process of using a trained model to generate predictions or classifications based on new data. However, recent demand for both training and inferencing of ML models has required ever more powerful and complex GPUs. These more powerful and complex GPUs not only require more power but also need more effective cooling.

### SUMMARY

This section generally summarizes the disclosure and is not a comprehensive explanation of its full scope or all its features.

In one embodiment, a system includes a closed loop having a first cooling device configured to cool a component of an electrical load, a first open loop configured to cool a coolant of the closed loop, and a second open loop having a second cooling device configured to selectively cool the component of the electrical load. The second cooling device may be configured to cool the component of the electrical load when a power source that emits water as a byproduct of operation is utilized to at least partially provide power to the electrical load.

In another embodiment, a control system for controlling the cooling of a component of an electrical load using a cooling system comprising a closed loop having a first cooling device and an open loop having a second cooling device includes a memory in communication with a processor. The memory has instructions that, when executed by the processor, cause the processor to actuate a valve to direct water to the open loop when a power source that emits the water as a byproduct of operation is utilized to at least partially provide power to the electrical load.

In yet another embodiment, a method for cooling a component of an electrical load using a cooling system comprising a closed loop having a first cooling device and an open loop having a second cooling device includes the step of directing water to the open loop when a power source that emits the water as a byproduct of operation is utilized to at least partially provide power to the electrical load.

Further areas of applicability and various methods of enhancing the disclosed technology will become apparent from the description provided. The description and specific examples in this summary are intended for illustration only and are not intended to limit the scope of the present disclosure.

### BRIEF DESCRIPTION OF THE DRAWINGS

The accompanying drawings, which are incorporated in and constitute a part of the specification, illustrate various systems, methods, and other embodiments of the disclosure. It will be appreciated that the illustrated element boundaries (e.g., boxes, groups of boxes, or other shapes) in the figures represent one embodiment of the boundaries. In some embodiments, one element may be designed as multiple elements or multiple elements may be designed as one element. In some embodiments, an element shown as an internal component of another element may be implemented as an external component and vice versa. Furthermore, elements may not be drawn to scale.

FIG. 1 illustrates one example of a system for providing supplemental power and cooling to one or more server racks.

FIG. 2 illustrates another example of a system for providing supplemental power and cooling to one or more server racks.

FIG. 3 illustrates a more detailed view of a direct-to-chip (“DTC”) cooling device for cooling one or more chips of a server rack.

FIG. 4 illustrates a more detailed view of a rear door heat exchanger for providing cooling to one or more server racks.

FIG. 5 illustrates a block diagram of a control system that controls one or more systems or subsystems so as to provide supplemental power and cooling to one or more server racks.

FIG. 6 illustrates a method for providing supplemental power and cooling to one or more server racks.

FIG. 7 illustrates a method for closing an open cooling loop when a water level falls below a threshold.

### DETAILED DESCRIPTION

Described are systems and methods for selectively providing supplemental cooling to one or more components of an electrical load. In one example, the electrical load may be one or more server racks, and the components may be one or more chips, such as GPUs and/or CPUs. The system may include a closed loop that utilizes a first cooling device, which may be a DTC cooling device, which is connected to a closed loop. Coolant within the closed loop travels through the DTC cooling device and cools the one or more components. The coolant within the closed loop is cooled by a heat exchanger connected to a first open loop, which uses water as a coolant.

When a power demand and/or heat generated by the electrical load exceeds a threshold, a supplemental power source that generates water as a byproduct of operation, such as a hydrogen fuel cell, is utilized to provide supplemental power to the electrical load. In addition, water generated by the supplemental power source may be provided to a second open cooling loop that is connected to a second cooling device, which may be a rear door heat exchanger, which is configured to provide supplemental cooling to the one or more components of the electrical load. As such, the systems and methods described herein not only provide supplemental power when needed but also provide supplemental cooling by utilizing water generated by the supplemental power source.

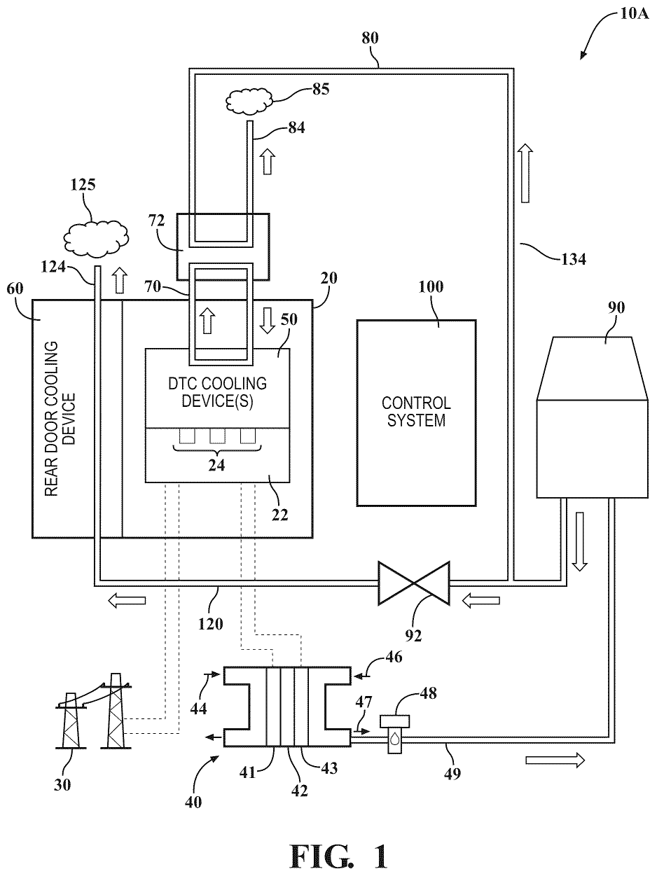

Referring to FIG. 1, illustrated is one example of a system 10A for providing power and/or cooling to an electrical load, which, in this example, is a server rack 20. It should be understood that the server rack 20 may be a single server rack or may be multiple server racks. The server rack 20 may include one or more rack servers 22, sometimes referred to as blades, which can include one or more components 24, such as random-access memory, storage, network interfaces, and power supplies. In addition, these one or more components 24 can also include processing units, such as one or more GPUs and/or CPUs. In particular, GPUs may be used in the server rack 20 and are widely used in ML data centers due to their ability to handle complex and computationally intensive tasks required for training and running machine learning models.

Generally, the server rack 20 receives power from a primary power source 30. In one example, the primary power source 30 may be an electrical grid. However, it should be understood that the primary power source 30 can vary from application to application. As such, the primary power source 30 can vary significantly and can include any other source capable of producing power to power the server rack 20.

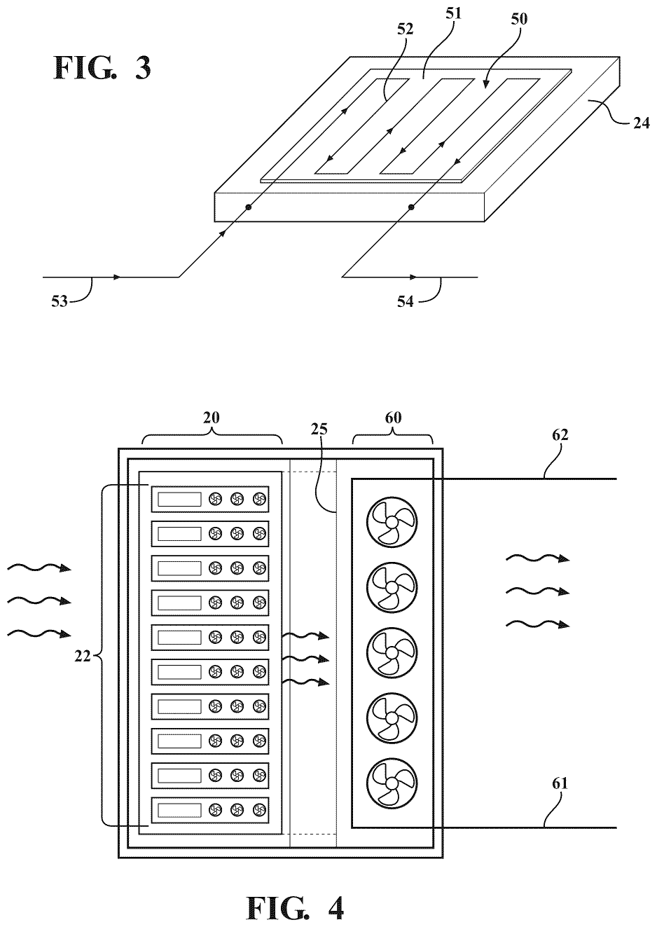

Cooling the components 24 of the rack server 22 may be accomplished utilizing a first cooling device, in this example, a DTC cooling device 50. As will be explained later when describing FIG. 3, the DTC cooling device 50, which may include one or more DTC cooling devices, involves delivering a coolant, which may contain glycol, directly to the surface of the components 24. In this example, the DTC cooling device 50 is connected to a closed loop 70 that allows the movement of the coolant to flow through micro channels within the DTC cooling device 50. In one example, the coolant within the closed loop 70 may have a boiling and/or freezing point greater than that of water. While not shown, it should be understood that the closed loop 70 may include one or more pumps, valves, or other necessary components controlled by a control system 100 that move the coolant through the closed loop 70 and the DTC cooling device 50.

As such, heat is transferred from the components 24 to the coolant within the closed loop 70. In order to cool the coolant within the closed loop 70, a first open loop 80 is utilized that receives water from a cooling tower 90 and transfers this water to a heat exchanger 72 that cools the coolant within the closed loop 70 by utilizing the water located within the first open loop 80. Like before, the first open loop 80 may include one or more pumps, valves, or other necessary components controlled by the control system 100 that move the water through the first open loop 80 and the heat exchanger 72. Eventually, the water within the first open loop 80 is directed towards an exit 84 of the first open loop 80 and may be in the form of steam 85.

There may be some cases where supplemental power and/or cooling may be necessary to cool the components 24 of the rack servers 22 forming the server rack 20. This may occur when power drawn by the server rack 20 exceeds a threshold and/or when a temperature exceeds the threshold caused by the operation of the server rack 20. As mentioned before, the server racks 20 and the components 24 forming the server racks 20 can demand significant amounts of electricity and generate significant amounts of heat when operating in peak conditions.

Moreover, as will explained in greater detail later, the control system 100 can monitor the power demand and/or heat generated by the operation of the server rack 20 to determine when supplemental power should be provided to the server rack 20. This can be based on a threshold power demand and/or temperature. When supplemental power and/or cooling is required, supplemental power may be provided to the server rack 20 by a secondary power source, which may be one or more hydrogen fuel cells 40.

The hydrogen fuel cell 40 operates by converting hydrogen gas 44 into electricity through a chemical reaction, with water being a byproduct of this chemical reaction. As such, in this example, the hydrogen fuel cell 40 includes an anode 41, an electrolyte 42, and a cathode 43. As is well known, a hydrogen gas 44 enters into the anode 41 and is split into protons and electrons, and air 46 is provided to the cathode 43. The protons and electrons separated by the anode 41 take different paths to the cathode 43, with the protons moving through the electrolyte 42 to the cathode 43 and the electrons traveling through the external circuit, in this case, the server rack 20, to the cathode 43, thus creating a flow of electricity. The protons, electrons, and air 46 combine to produce water 47 as a byproduct of the operation of the hydrogen fuel cell 40.

The water 47 produced by the operation of the hydrogen fuel cell 40 may be provided to a purifier 48. Generally, the purifier 48 can be a filter capable of filtering one or more impurities from the water 47. For example, in some cases, oil, dirt, environmental contamination, or other impurities may come into contact with the water 47, necessitating the need for the purifier 48. However, it should be understood that if the water 47 produced during the operation of the hydrogen fuel cell 40 is of the appropriate purity, the purifier 48 may not be necessary and may not form part of the system 10A. After being purified (if necessary), the water 47 is then provided to the cooling tower 90 via a fluid connection 49.

When the hydrogen fuel cell 40 is providing supplemental power to the server rack 20, the control system 100 controls one or more actuators to actuate a valve 92 to an open position. Conversely, in situations where the hydrogen fuel cell 40 is not providing supplemental power to the server rack 20, the control system 100 may control the one or more actuators to actuate the valve 92 to a closed position.

However, when in the open position, water within the cooling tower 90 is allowed to flow into a second open loop 120. Like before, the second open loop 120 may include the appropriate pumps, valves, or other components to allow the flow of water from the cooling tower 90 to an exit 124. In this case, when the valve 92 is open, water flows to a second cooling device, which may be a rear door cooling device 60, which can provide additional cooling to the server rack 20. In this example, as will be explained later when describing FIG. 4, the rear door cooling device 60 may be mounted directly onto the back of the server rack 20. The rear door cooling device 60 uses water within the second open loop 120 to absorb heat from the hot air exiting the server rack 20. As explained previously, the water within the second open loop 120 is provided to the exit 124 and may be in the form of steam 125.

As such, when supplemental power is provided to the server rack 20, water generated as a byproduct of producing the supplemental power by the hydrogen fuel cell 40 can be utilized by the rear door cooling device 60 to provide supplemental cooling to the server rack 20. In addition, the water generated by the operation of the hydrogen fuel cell 40 may also be provided to the first open loop 80.

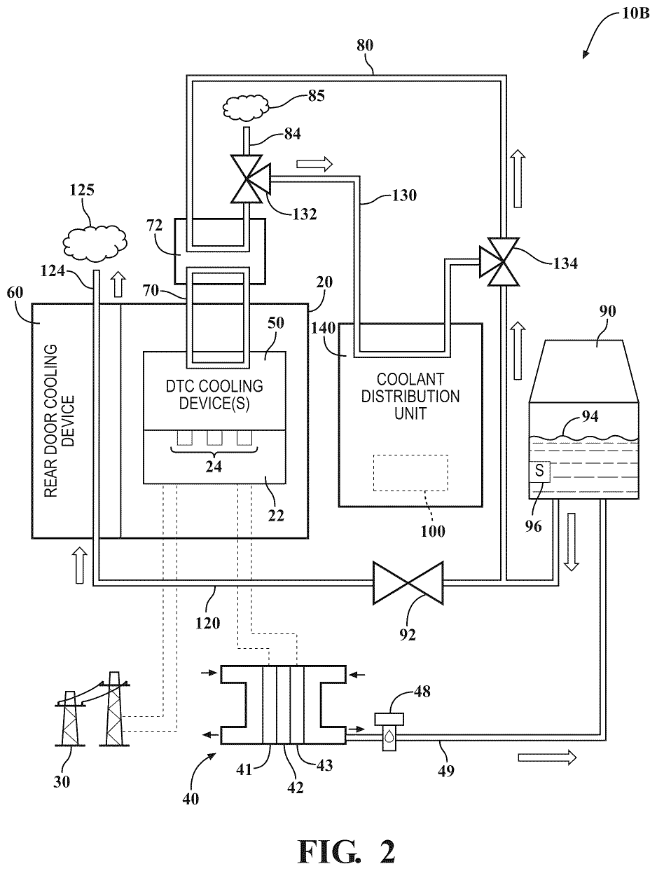

FIG. 2 illustrates a system 10B, which is a variation of the system 10A described in FIG. 1. As such, like reference numerals have been utilized to refer to like components unless specifically mentioned, and any prior description of these components is equally applicable to this example. The system 10B also includes a sensor 96 for monitoring the water level 94 within the cooling tower 90. There may be some situations, especially when the hydrogen fuel cell 40 is not in operation and therefore not producing water to refill the cooling tower 90, wherein the water level 94 within the cooling tower 90 drops to a level that may result in the first open loop 80 not receiving enough water to properly cool the coolant within the closed loop 70.

When the water level 94 drops below a threshold, as indicated by one or more sensor signals from the sensor 96, the control system 100 may actuate the valves 132 and 134 to direct water within the first open loop 80 from the exit 84 to a loop segment 130 and back to the first open loop 80. Moreover, the valve 132 directs water to the loop segment 130 and not the exit 84. The valve 134 directs water from the loop segment 130 back into the first open loop 80. Essentially, by directing water from the exit 84 to the loop segment 130, the first open loop 80 turns into a closed loop, preventing water from escaping as steam 85.

The loop segment 130 may also pass through a coolant distribution unit 140 that includes appropriate valves, pumps, or other components so as to move water through the first open loop 80 and the loop segment 130. In addition, the coolant distribution unit 140 may also include one or more heat exchangers, chillers, or other similar components for cooling the water within the first open loop 80 and the loop segment 130. By cooling the water within the first open loop 80 and the loop segment 130, the cooled water can then be provided to the heat exchanger 72, which can be used to cool the coolant within the closed loop 70.

FIG. 3 illustrates a more detailed view of the DTC cooling device 50. It should be noted that, in this example, only a single component 24 is being cooled. However, it should be understood that the DTC cooling device 50 could be cooling numerous components, such as chips. Here, illustrated is the component 24, which could be a GPU that may be found in the rack server 22. The DTC cooling device 50 includes a cooling plate 51 that includes a zigzag channel 52 that has an inlet line 53 that receives coolant from the closed loop 70. The coolant travels along the zigzag channel 52, transferring heat generated by the component 24 to the coolant located within the zigzag channel 52. The coolant is then output to an outlet line 54, where it is returned to the closed loop 70, where the coolant can be cooled by the heat exchanger 72 using water within the first open loop 80.

FIG. 4 illustrates a more detailed view of the rear door cooling device 60. Here, illustrated is the server rack 20 including several rack servers 22 that generate heat during their operation. The rear door cooling device 60 is mounted to the back door 25 of the server rack 20, where it is positioned to absorb heat expelled from the rack servers 22, which may be aided by the use of one or more fans. The rear door cooling device 60 receives water from the second open loop 120 via a fluid line 61, which is then circulated through coils or plates. As hot air from the rack servers 22 passes over these coils or plates, heat from the air is transferred to the water, which is then returned to the second open loop 120 via a fluid line 62, where it can be expelled as steam 85.

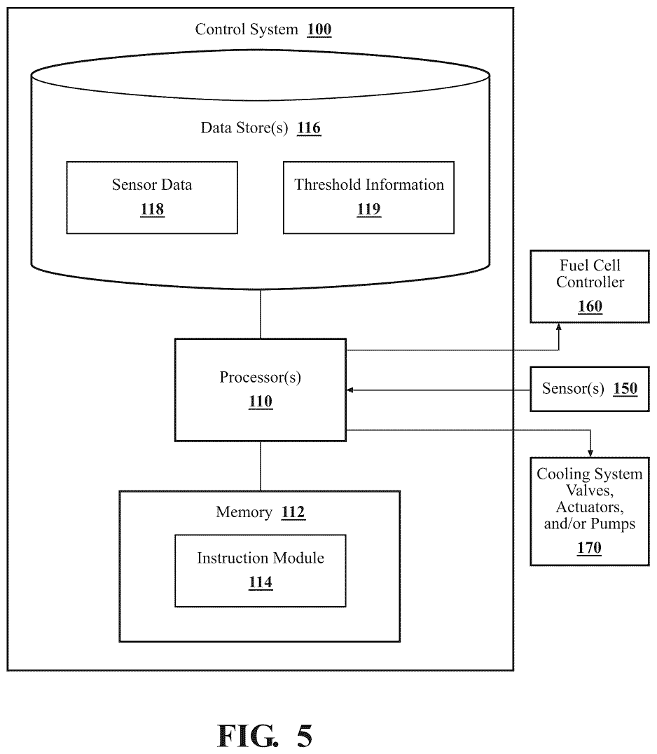

With reference to FIG. 5, one embodiment of the control system 100 for controlling one or more systems and or subsystems of the systems 10A and/or 10B of FIGS. 1 and 2, respectively, is further illustrated. As shown, the control system 100 includes one or more processor(s) 110. Accordingly, the processor(s) 110 may be a part of the control system 100, or the control system 100 may access the processor(s) 110 through a data bus or another communication path. In one or more embodiments, the processor(s) 110 is an application-specific integrated circuit that is configured to implement functions associated with an instruction module 114. In general, the processor(s) 110 is an electronic processor, such as a microprocessor, which is capable of performing various functions as described herein. In one embodiment, the control system 100 includes a memory 112 that stores the instruction module 114. The memory 112 is a random-access memory (RAM), read-only memory (ROM), a hard disk drive, a flash memory, or other suitable memory for storing the instruction module 114. The instruction module 114 is, for example, computer-readable instructions that, when executed by the processor(s) 110, cause the processor(s) 110 to perform the various functions disclosed herein.

Furthermore, in one embodiment, the control system 100 includes one or more data store(s) 116. The data store(s) 116 is, in one embodiment, an electronic data structure such as a database that is stored in the memory 112 or another memory and that is configured with routines that can be executed by the processor(s) 110 for analyzing stored data, providing stored data, organizing stored data, and so on. Thus, in one embodiment, the data store(s) 116 stores data used by the instruction module 114 in executing various functions. In one embodiment, the data store(s) 116 includes sensor data 118 and threshold information 119, along with, for example, other information that is used by the instruction module 114.

The sensor data 118 may include data collected from one or more sensor(s) 150. In one example, the one or more sensor(s) 150 may collect information related to the power demand of the server rack 20, the heat generated during the operation of the server rack 20, and/or the water level 94 of the cooling tower 90. As such, the one or more sensor(s) 150 may include the sensor 96. Information regarding the heat can include the temperature of one or more components or areas near components making up the server rack 20, including GPUs and/or CPUs, coolant temperatures, air temperatures, etc. The threshold information 119 can include information regarding one or more conditions regarding the server rack 20 and/or the water level 94 of the cooling tower 90. For example, the threshold information 119 can include a power threshold indicating the maximum amount of power that the server rack 20 should draw from the primary power source 30, a temperature threshold indicating the maximum temperature of one or more components of the server rack 20, and/or a water level 94 suitable for providing water to the first open loop 80. As will be explained later, when these thresholds are crossed, the control system 100 will take appropriate action.

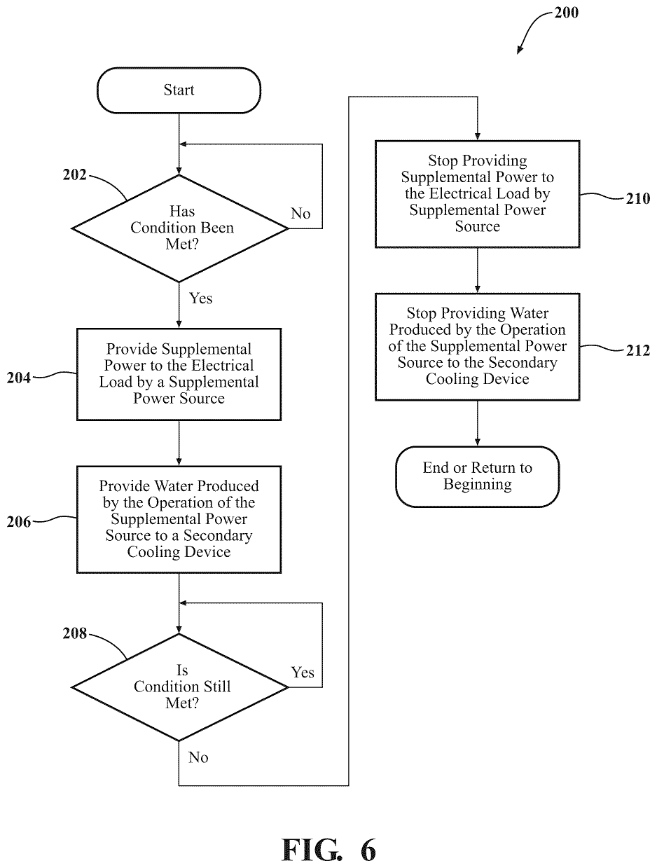

As mentioned before, the instruction module 114 contains instructions that cause the processor(s) 110 to perform any of the methodologies described herein. With reference to FIG. 6, illustrated is a method 200 for providing supplemental power and/or cooling to the server rack 20. The method 200 will be described from the viewpoint of the systems 10A and/or 10B in FIGS. 1 and 2, respectively. However, it should be understood that this is just one example of implementing the method 200. While the method 200 is discussed in combination with the systems 10A and/or 10B, it should be appreciated that the method 200 is not limited to being implemented within the systems 10A and/or 10B but is instead one example of a system that may implement the method 200. As such, the method 200 may be embodied within the instruction module 114 as processor-executable instructions that, when executed by the processor(s) 110, cause the processor(s) 110 to perform the method 200.

In step 202, the method 200 continuously monitors if a particular condition has been met. This may be achieved by having the instruction module 114 cause the processor(s) 110 to continuously monitor the sensor data 118 collected by the sensor(s) 150. As mentioned before, the sensor data 118 can include information relating to the power drawn by the server rack 20 and/or temperature information related to the operation of the server rack 20. For example, the temperature information can include the temperature of the components 24 or near components forming the server rack 20. For example, the operating temperature for a particular GPU or CPU could be monitored to determine if a certain condition has been met. In addition, other temperatures can also be monitored, such as the temperature of the coolant within the closed loop 70 and/or the water within the first open loop 80 and/or the second open loop 120.

The condition can be met when a certain threshold has been passed. In one example, the threshold may be a power threshold that can relate to a certain amount of power drawn by the server rack 20. When the power drawn by the server rack 20 surpasses the power threshold, the condition can be satisfied. In another example, the threshold may be a temperature threshold related to the temperature of one or more particular components of the server rack 20. When the temperature of one or more particular components surpasses the temperature threshold, the condition can be satisfied.

If the condition has been satisfied, the method 200 proceeds to step 204. Otherwise, the method 200 continues to monitor the sensor data 118 to determine if the condition has been met. In step 204, the instruction module 114 causes the processor(s) 110 to provide supplemental power to the electrical load, in this case, the server rack 20, by a supplemental power source. This may be accomplished by having the processor(s) 110 (shown in FIG. 5) of the control system 100 send one or more commands to a fuel cell controller 160 that controls the operation of the hydrogen fuel cell 40. As explained previously, the supplemental power source can be the hydrogen fuel cell 40. In addition, as shown in step 206, water produced by the operation of the secondary power source (i.e., the hydrogen fuel cell 40) can be provided to the cooling system, in this case, the cooling tower 90.

In step 206, the instruction module 114 causes the processor(s) 110 to provide water produced by the operation of the supplemental power source (i.e., the hydrogen fuel cell 40) to a secondary cooling device, which may be the rear door cooling device 60. Moreover, the instruction module 114 may cause the processor(s) 110 to control one or more actuators that actuate the valve 92 to an open position allowing water to flow from the cooling tower 90 to the second open loop 120 towards the exit 124. The instruction module 114 may further cause the processor(s) 110 to control other valves, actuators, and/or pumps 170 if necessary. During this travel, the water is provided to the rear door cooling device 60, which provides supplemental cooling to the server rack 20. As explained previously, in one example, when the server rack 20 is only receiving power from the primary power source 30, water may only be provided to the first open loop 80. When supplemental power is provided to the server rack 20 from the hydrogen fuel cell 40, the processor(s) 110 may control the valve 92 to also send water to the rear door cooling device 60.

It should be noted that the condition, either related to the power drawn by the server rack 20 and/or the temperature of one or more of the server racks 20 and/or the cooling system, the instruction module 114 causes the processor(s) 110 to continuously monitor the sensor data 118, as indicated in step 208. If the condition is still met, supplemental power provided by the hydrogen fuel cell 40 and supplemental cooling provided by sending water to the second open loop 120 will continue.

However, when the condition is no longer met, the method 200 proceeds to step 210, wherein the instruction module 114 causes the processor(s) 110 to shut down the secondary power source (i.e., the hydrogen fuel cell 40). In step 212, the instruction module 114 causes the processor(s) 110 to stop providing water to the second open loop 120, which can be accomplished by actuating the valve 92 to a closed position. After that, the method 200 may either stop or return to step 202.

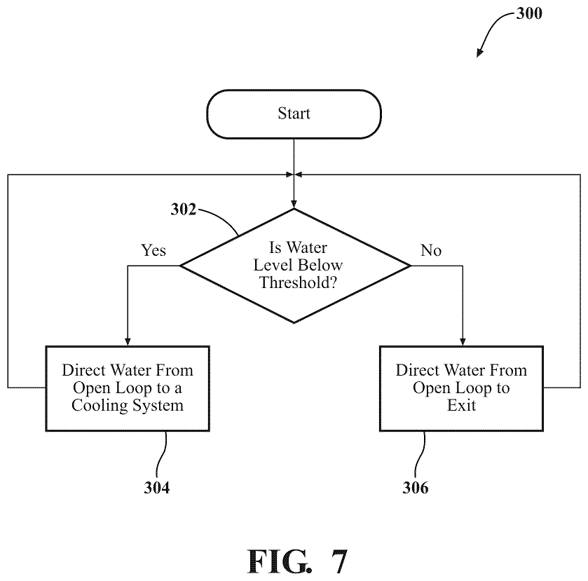

When describing the system 10B, it was noted that the water level 94 of the cooling tower 90 may drop to a level where it becomes advisable to no longer provide water to the first open loop 80. FIG. 7 illustrates a method 300 for controlling the system 10B when such an occurrence happens. The method 300 may be executed concurrently along with the method 200. As such, the method 300 will be described from the viewpoint of the system 10B in FIG. 2. However, it should be understood that this is just one example of implementing the method 300. While the method 300 is discussed in combination with the system 10B, it should be appreciated that the method 300 is not limited to being implemented within the system 10B but is instead one example of a system that may implement the method 300. As such, the method 300 may be embodied within the instruction module 114 as processor-executable instructions that, when executed by the processor(s) 110, cause the processor(s) 110 to perform the method 300.

In step 302, the instructions within the instruction module 114, when executed by the processor(s) 110, cause the processor(s) 110 to determine if the water level 94 is below a threshold. This may be accomplished by monitoring the sensor data 118 by the processor(s) 110, which may be provided by the sensor 96. If it is determined that the water level 94 is below a threshold amount, the method 300 proceeds to step 304. Otherwise, the method 300 proceeds to step 306.

In step 304, when the water level 94 is below a threshold, the instructions within the instruction module 114, when executed by the processor(s) 110, cause the processor(s) 110 to direct water to a cooling system, which may be located within the coolant distribution unit 140. This can be accomplished by actuating the valve 132 to direct water to the loop segment 130 instead of the exit 84. In addition, the valve 134 may be actuated to direct water from the coolant distribution unit 140 back to the first open loop 80, essentially turning the first open loop 80, along with the loop segment 130, into a closed loop system.

In step 304, when the water level 94 is above a threshold, the instructions within the instruction module 114, when executed by the processor(s) 110, cause the processor(s) 110 to direct water within the first open loop 80 towards the exit 84. This may be accomplished by actuating the valve 132 such that water is directed towards the exit 84 and not the loop segment 130. In addition, the valve 134 may be adjusted so that water can be provided from the cooling tower 90 to the first open loop 80 and not towards the coolant distribution unit 140.

After either step 302 or 304 is accomplished, the method 300 may either end or start over from the beginning, as shown.

Detailed embodiments are disclosed herein. However, it is to be understood that the disclosed embodiments are intended only as examples. Therefore, specific structural and functional details disclosed herein are not to be interpreted as limiting but merely as a basis for the claims and as a representative basis for teaching one skilled in the art to variously employ the aspects herein in virtually any appropriately detailed structure. Further, the terms and phrases used herein are not intended to be limiting but rather to provide an understandable description of possible implementations. Various embodiments are shown in FIGS. 1-7, but the embodiments are not limited to the illustrated structure or application.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. Any processing system or another apparatus adapted for carrying out the methods described herein is suited. A typical combination of hardware and software can be a processing system with computer-usable program code that, when being loaded and executed, controls the processing system such that it carries out the methods described herein. The systems, components, and/or processes also can be embedded in a computer-readable storage, such as a computer program product or other data programs storage device, readable by a machine, tangibly embodying a program of instructions executable by the machine to perform methods and processes described herein. These elements can also be embedded in an application product, which comprises all the features enabling the implementation of the methods described herein and which, when loaded in a processing system, is able to carry out these methods.

Furthermore, arrangements described herein may take the form of a computer program product embodied in one or more computer-readable media having computer-readable program code embodied, e.g., stored, thereon. Any combination of one or more computer-readable media may be utilized. The computer-readable medium may be a computer-readable signal medium or a computer-readable storage medium. The phrase “computer-readable storage medium” means a non-transitory storage medium. A computer-readable storage medium may be, for example, but not limited to, an electronic, magnetic, optical, electromagnetic, infrared, or semiconductor system, apparatus, or device, or any suitable combination of the preceding. More specific examples (a non-exhaustive list) of the computer-readable storage medium would include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or any suitable combination of the preceding. In the context of this document, a computer-readable storage medium may be any tangible medium that can contain or store a program for use by or in connection with an instruction execution system, apparatus, or device.

Generally, module as used herein includes routines, programs, objects, components, data structures, and so on that perform particular tasks or implement particular data types. In further aspects, a memory generally stores the noted modules. The memory associated with a module may be a buffer or cache embedded within a processor, a RAM, a ROM, a flash memory, or another suitable electronic storage medium. In still further aspects, a module as envisioned by the present disclosure is implemented as an application-specific integrated circuit (ASIC), a hardware component of a system on a chip (SoC), as a programmable logic array (PLA), or as another suitable hardware component that is embedded with a defined configuration set (e.g., instructions) for performing the disclosed functions.

Program code embodied on a computer-readable medium may be transmitted using any appropriate medium, including but not limited to wireless, wireline, optical fiber, cable, RF, etc., or any suitable combination of the preceding. Computer program code for carrying out operations for aspects of the present arrangements may be written in any combination of one or more programming languages, including an object-oriented programming language such as Java™, Smalltalk, C++, or the like, and conventional procedural programming languages, such as the “C” programming language or similar programming languages. The program code may execute entirely on the user's computer, partly on the user's computer, as a stand-alone software package, and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider).

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

Aspects herein can be embodied in other forms without departing from the spirit or essential attributes thereof. Accordingly, reference should be made to the following claims rather than to the preceding specification, as indicating the scope hereof.

What is claimed is:

1. A system comprising:
a closed loop having a first cooling device configured to cool a component of an electrical load;
a first open loop configured to cool a coolant of the closed loop; and
a second open loop having a second cooling device configured to selectively cool the component of the electrical load.

2. The system of claim 1, wherein the second cooling device is configured to cool the component of the electrical load when a power source that emits water as a byproduct of operation is utilized to at least partially provide power to the electrical load.

3. The system of claim 2, wherein at least a portion of the water emitted by the power source is provided to the second open loop.

4. The system of claim 2, wherein at least a portion of the water emitted by the power source is provided to the first open loop.

5. The system of claim 1, wherein the coolant of the closed loop has a boiling point greater than water.

6. The system of claim 5, wherein the coolant includes glycol.

7. The system of claim 1, wherein:
the first cooling device is a direct-to-chip cooling device; and
the second cooling device is a rear door heat exchanger.

8. The system of claim 1, wherein:
the electrical load is one or more server racks; and
the component is one or more chips of the one or more server racks.

9. The system of claim 1, further comprising:
a valve having a first position and a second position;
when in the first position, water provided to the first open loop is directed to an exit of the first open loop; and
when in the second position, the water provided to the first open loop is directed to a cooling system to cool the water of the first open loop.

10. A control system for controlling a cooling of a component of an electrical load using a cooling system comprising a closed loop having a first cooling device and an open loop having a second cooling device, the control system comprising a memory in communication with a processor, the memory having instructions that, when executed by the processor, cause the processor to:
actuate a valve to direct water to the open loop when a power source that emits the water as a byproduct of operation is utilized to at least partially provide power to the electrical load.

11. The control system of claim 10, wherein the memory further comprises instructions that, when executed by the processor, cause the processor to activate the power source when a condition has been satisfied.

12. The control system of claim 11, wherein the condition is at least one of:
when a power demand by the electrical load has exceeded a power threshold; and
when a temperature of the electrical load exceeds a temperature threshold.

13. The control system of claim 10, at least a portion of the water emitted by the power source is provided to the open loop.

14. The control system of claim 10, wherein:
the first cooling device is a direct-to-chip cooling device; and
the second cooling device is a rear door heat exchanger.

15. The control system of claim 10, wherein:
the electrical load is one or more server racks; and
the component is one or more chips of the one or more server racks.

16. A method for cooling a component of an electrical load using a cooling system comprising a closed loop having a first cooling device and an open loop having a second cooling device, the method comprising directing water to the open loop when a power source that emits the water as a byproduct of operation is utilized to at least partially provide power to the electrical load.

17. The method of claim 16, further comprising activating the power source when a condition has been satisfied, the condition is at least one of:
when a power demand by the electrical load has exceeded a power threshold; and
when a temperature of the electrical load exceeds a temperature threshold.

18. The method of claim 16, wherein at least a portion of the water emitted by the power source is provided to the open loop.

19. The method of claim 16, wherein:
the first cooling device is a direct-to-chip cooling device; and
the second cooling device is a rear door heat exchanger.

20. The method of claim 16, wherein:
the electrical load is one or more server racks; and
the component is one or more chips of the one or more server racks.
